(19) United States
(12) Patent Application Publication
(10) Pub. No.: US 2016/0071707 A1
(43) Pub. Date: Mar. 10, 2016

(54) PROCESSING APPARATUS

(71) Applicant: TOKYO ELECTRON LIMITED, Tokyo (JP)

(72) Inventors: Shinji FURUKAWA, Yamanashi (JP); Hiroyuki TOSHIMA, Yamanashi (JP); Tooru KITADA, Yamanashi (JP); Kanto NAKAMURA, Yamanashi (JP); Kazunaga ONO, Yamanashi (JP)

(21) Appl. No.: 14/842,821

(22) Filed: Sep. 1, 2015

(30) Foreign Application Priority Data
Sep. 4, 2014 (JP) 2014-180292

(51) Int. Cl. H01J 37/34; H01J 37/32

(52) U.S. Cl. CPC H01J 37/3488; H01J 37/32733

(57) ABSTRACT

A processing apparatus includes a processing chamber, a rotatable mounting table, a cooling mechanism and a driving mechanism. A sputtering target is provided in the processing chamber. The rotatable mounting table is provided in the processing chamber and configured to mount thereon an object to be processed. The cooling mechanism is configured to cool the mounting table. The driving mechanism is configured to change a relative position of the mounting table with respect to the cooling mechanism. The driving mechanism changes a conductivity of heat from the mounting table to the cooling mechanism at least by switching a first state in which the mounting table and the cooling mechanism are separated from each other and a second state in which the mounting table and the cooling mechanism become close to each other.

### CROSS-REFERENCE TO RELATED APPLICATIONS

This application claims priority to Japanese Patent Application No. 2014-180292 filed on Sep. 4, 2014, the entire contents of which are incorporated herein by reference.

### FIELD OF THE INVENTION

The disclosure relates to a processing apparatus including a processing chamber in which a sputtering target is provided; and more particularly, to a processing apparatus including a cooling mechanism for performing low temperature processing.

### BACKGROUND OF THE INVENTION

Conventionally, there is known a processing apparatus for depositing a film on a substrate (object to be processed) by sputtering a target (see Japanese Patent Application Publication No. 2012-140672). Further, there are known film forming techniques using a substrate cooled to an extremely low temperature (see Japanese Patent Application Publication Nos. 2013-232273 and 2014-10880).

In order to form a magnetic film having sufficient in-plane uniformity, a mounting table needs to be rotated during sputtering. If the film formation can be performed in a state where both of sufficient rotation and cooling are achieved, it is possible to form the magnetic film having excellent characteristics.

However, in a conventional processing apparatus, as a chiller to be fixed to the mounting table, a small-size chiller having a low cooling capacity needs to be employed in consideration of the rotation of the mounting table. Therefore, it is difficult to perform the film formation using sputtering while achieving both of sufficient rotation and cooling of the object to be processed.

### SUMMARY OF THE INVENTION

In view of the above, the disclosure provides a processing apparatus capable of performing film formation using sputtering in a state where sufficient rotation and cooling of an object to be processed are achieved.

In accordance with an aspect of the present invention, there is provided a processing apparatus including a processing chamber, a rotatable mounting table, a cooling mechanism and a driving mechanism. A sputtering target is provided in the processing chamber. The rotatable mounting table is provided in the processing chamber and configured to mount thereon an object to be processed. The cooling mechanism is configured to cool the mounting table. The driving mechanism is configured to change a relative position of the mounting table with respect to the cooling mechanism. The driving mechanism changes a conductivity of heat from the mounting table to the cooling mechanism at least by switching a first state in which the mounting table and the cooling mechanism are separated from each other and a second state in which the mounting table and the cooling mechanism become close to each other.

### BRIEF DESCRIPTION OF THE DRAWINGS

The objects and features of the disclosure will become apparent from the following description of embodiments, given in conjunction with the accompanying drawings, in which:

FIG. 1 shows an overall configuration of a processing apparatus in accordance with an embodiment;

FIG. 2 shows principal parts of the processing apparatus;

FIGS. 3A to 3C explain movement of a mounting table;

FIGS. 4A and 4B explain cooling of the mounting table;

FIG. 5 shows a processing apparatus in which a plurality of targets is provided;

FIG. 6 is a timing chart showing relation between a processing time and a substrate temperature; and

FIG. 7 is another timing chart showing relation between the processing time and the substrate temperature.

### DETAILED DESCRIPTION OF THE EMBODIMENTS

Hereinafter, a processing apparatus in accordance with an embodiment will be described. Like reference numerals will be used for like parts and redundant description thereof will be omitted.

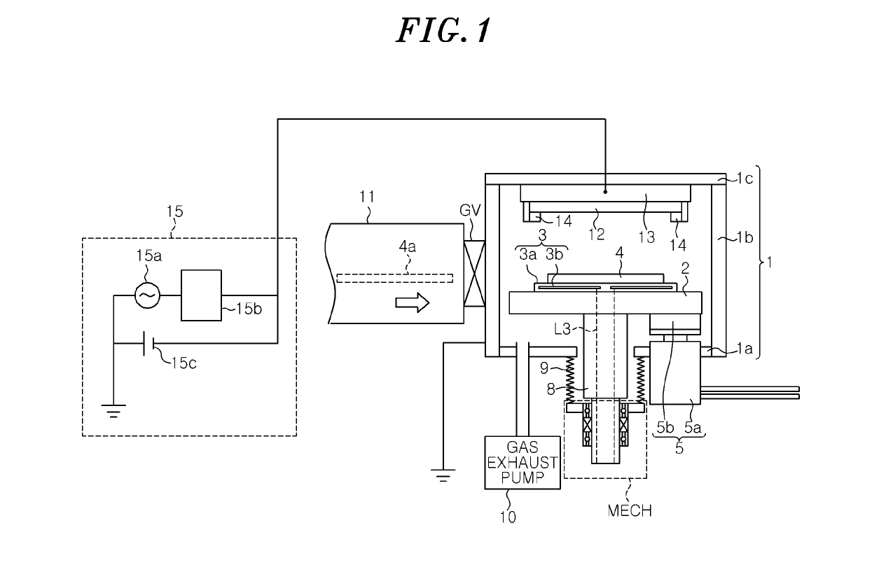

FIG. 1 shows an overall configuration of a processing apparatus.

The processing apparatus includes a processing chamber 1. Installed in the processing chamber 1 are a mounting table 2 (stage) and an electrostatic chuck 3 fixed to the mounting table 2. A substrate 4 (object to be processed) is mounted on the electrostatic chuck 3. The processing chamber 1 has a bottom plate 1a at a lower part thereof, a cylindrical surrounding body 1b surrounding an outer periphery of the bottom plate 1a, and a ceiling plate 1c provided on the cylindrical surrounding body 1b to seal the cylindrical surrounding body 1b.

A target holder 13 is fixed to the ceiling plate 1c provided at an upper portion of the processing chamber 1. A claw member 14 is fixed to the target holder 13. A target 12 is held by the target holder 13 with its peripheral portion interposed between the target holder 13 and the claw member 14.

The target holder 13 is a conductor. An insulator is disposed between the target holder 13 and the ceiling plate 1c. A voltage from a power supply 15 for plasma generation is applied to the target holder 13. The processing chamber 1 including the ceiling plate 1c has a ground potential. A high frequency potential is applied from the power supply 15 for plasma generation to the target holder 13 and the target 12. The power supply 15 for plasma generation is used for sputtering the target 12 by ions in plasma generated in the processing chamber 1. In order to generate the plasma, the processing chamber 1 is filled with a rare gas such as Ar, Kr, Ne or the like.

The power supply 15 for plasma generation includes an AC power supply 15a for a high frequency and a matching unit 15b to apply an AC voltage between the target 12 and the ground potential. If necessary, the power supply 15 for plasma generation may include a DC power supply 15c in parallel to the AC power supply 15a. The DC power supply 15c can change the amplitude center of the potential applied to the target 12. Although a high frequency of 13.56 MHz or the like is generally used for plasma generation, it is possible to use another frequency and also to use a DC power supply. In addition, magnetron sputtering can be performed by providing a magnet near the target 12 and apply a magnetic field to a surface of the target.

The electrostatic chuck 3 fixed onto the mounting table 2 includes an insulating layer 3a, and an electrostatic chuck electrode plate 3b embeded in the insulating layer 3a. By applying a predetermined potential to the electrostatic chuck electrode plate 3b through a wiring L3, the substrate 4 can be held on the electrostatic chuck 3. The wiring 13 rotates together with the electrostatic chuck 3. The wiring L3 can be electrically connected to a power supply for supplying a power thereto through a slip ring. If necessary, a passage can be formed at the electrostatic chuck 3 to supply a cooling gas such as He or the like to an interface between the electrostatic chuck 3 and the substrate 4.

A gas exhaust pump 10 communicates with the processing chamber 1 to exhaust a gas therein. Therefore, a pressure in the processing chamber 1 is decreased to a level at which plasma can be generated. When a high frequency voltage is applied to the target 12 from the power supply 15 for plasma generation, plasma is generated near the target 12 and the target 12 is sputtered. Sputtered atoms or molecules are deposited on the surface of the substrate 4 which faces the target 12.

In the case of depositing a magnetic film (a film containing a ferromagnetic substance such as Ni, Fe, Co or the like), CoFe, FeNi, or NiFeCo may be used as a material of the target 12. A mixture of such materials and another element may also be used as the material of the target. By forming the magnetic film using a sputtering method in low temperature, it is possible to control thin film characteristics such as a crystal grain diameter, a film stress or the like.

A supporting shaft S extending in a vertical direction is fixed to the bottom surface of the mounting table 2. The supporting shaft 8 is connected to a rotating and linearly moving mechanism MECH. The rotating and linearly moving mechanism MECH can move the supporting shaft 8 in the vertical direction and rotate the supporting shaft 8. A bellows 9 is provided between the supporting shaft 8 and the rotating and linearly moving mechanism MECH, so that airtightness in the processing chamber 1 can be maintained even if the position of the supporting shaft 8 is shifted. The bellows 9 is a surrounding body extendible and contractable in the vertical direction. The surrounding body has an upper end fixed to the bottom plate 1a of the processing chamber 1 and a lower end fixed to an upper end of the rotating and linearly moving mechanism MECH.

The mounting table 2 is cooled by a cooling mechanism 5 fixed to the bottom plate 1a of the processing chamber 1. The cooling mechanism 5 includes a chiller 5a and a heat transfer mechanism 5b fixed to a cooling head 5a1 provided at a top portion of the chiller 5a. As described above, the mounting table 2 is provided in the processing chamber 1 and mounts thereon the substrate 4. Further, the mounting table 2 can rotate about a vertical shaft. The cooling mechanism 5 approaches or makes contact with the mounting table 2, thereby cooling the mounting table 2. Although any one of the mounting table 2 and the cooling mechanism 5 may be moved, the mounting table 2 is vertically moved in this embodiment.

The cooled mounting table 2 is moved upward and separated from the cooling mechanism 5. Next, the target 12 is sputtered and a film is formed on the substrate 4. When the processing of the substrate 4 is completed, the substrate 4 is unloaded to a transfer chamber 11 by a transfer mechanism (not shown). Thereafter, a next substrate 4a waiting in the transfer chamber 11 is loaded into the processing chamber 1 by the transfer mechanism and mounted/held on the electrostatic chuck 3 on the mounting table 2.

A gate valve GV is provided between the processing chamber 1 and the transfer chamber 11. The gate valve GV is opened during the transfer process and closed during the film formation.

Hereinafter, neighboring structures (principal parts) of the mounting table 2 will be described.

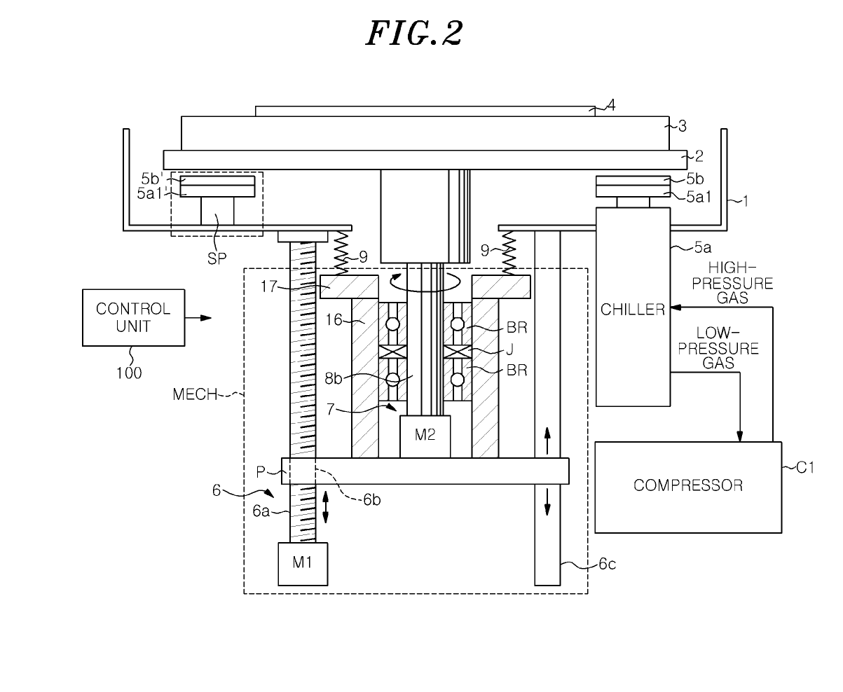

FIG. 2 shows the principal parts of the processing apparatus.

The rotating and linearly moving mechanism MECH includes a driving mechanism 6 for performing linear movement and a rotation mechanism 7 for performing rotation. The driving mechanism 6 shifts a relative position of the mounting table 2 with respect to the cooling mechanism 5 by performing linear movement in the vertical direction. Although various types of structures may be employed for the driving mechanism 6, the driving mechanism 6 has at least function which can switch a first state in which the mounting table 2 and the cooling mechanism 5 are separated from each other and a second state in which the mounting table 2 and the cooling mechanism 5 becomes close to each other by vertically moving the mounting table 2.

In this processing apparatus, the conductivity of heat from the mounting table 2 to the cooling mechanism 5 can be changed, because the driving mechanism 6 can selectively set the first state in which the mounting table 2 and the cooling mechanism 5 are separated from each other and the second state in which the mounting table 2 and the cooling mechanism 5 become close to each other. The second state is set when the mounting table 2 needs to be cooled. Accordingly, the heat of the mounting table 2 is transferred to the cooling mechanism 5. As a consequence, the mounting table 2 can be sufficiently cooled. Since the cooling mechanism 5 does not rotate together with the mounting table 2, one having a high cooling capacity may be employed as the cooling mechanism 5.

The first state is set when the sputtering needs to be performed. Accordingly, the mounting table 2 is physically separated from the cooling mechanism 5. As a consequence, the mounting table 2 can rotate freely. In this processing apparatus, the film formation using sputtering can be performed in a state where both of sufficient rotation and cooling of the substrate 4 mounted on the mounting table 2 are achieved.

A chiller used for a cryopump can be employed as the chiller 5a having a high cooling capacity.

The chiller 5a has the cooling head 5a1 at an upper portion of a main body. The cooling head 5a1 provides a cooling surface. The cooling surface is in contact with the heat transfer mechanism 5b and fixed thereto. The main body of the chiller 5a cools the cooling head 5a1 by a Gifford-McMahon cycle (G-M cycle) using a gas such as He or the like. In other words, a high-pressure gas is introduced into the chiller 5a from a compressor C1 and a low-pressure gas is sucked from the chiller 5a. When being expanded in the chiller 5a, the high-pressure gas is cooled.

The chiller 5a has a function of cooling the substrate 4 mounted on the electrostatic chuck 3 to a temperature ranging from about −263° C. to −60° C. The lower limit of the range is obtained by adding a temperature increase (e.g., about 2° C.) of the substrate 4 to a lowest cooling temperature (−265° C.) of the chiller 5a. The upper limit (−60° C.) of the range is lower than a lowest temperature that can be obtained by using a general coolant such as Galden (Registered Trademark). The chiller 5a is not limited to a G-M cycle refrigeration system.

A chiller using adiabatic expansion of He gas has an excellent freezing capacity and is suitable for cooling to an extremely low temperature. The G-M cycle refrigeration system generally includes a compressor for compressing He gas and sending the compressed He gas, a freezer having a piston for adiabatic expansion, and a flexible hose for connecting the compressor and the chiller. Further, the G-M cycle refrigeration system has a freezing capacity ten times greater than that of a Stirling-type refrigeration system.

The Stirling-type refrigeration system may be employed for structure of the cooling mechanism. In that case, heat is exchanged by repeatedly compressing and expanding He gas in a casing by reciprocal movement of the piston. Although a small-size Stirling-type refrigeration system may be employed, it has a lower cooling capacity than that of the G-M cycle refrigeration system.

In this processing apparatus, the shape of the heat transfer mechanism 5b is not particularly limited. A plurality of heat transfer mechanisms 5b may be provided at multiple locations. Alternatively, the heat transfer mechanism 5b may have a ring shape. For example, a heat transfer mechanism 5b′ and a cooling head 5a1′ may be provided at positions other than the top portion of the main body of the chiller 5a, as surrounded by a dotted line in FIG. 2. For example, both of the cooling head 5a1 and the heat transfer mechanism 5b may have the ring shape surrounding the supporting shaft 8. In that case, the cooling mechanism 5 includes: ring-shaped heat transfer mechanisms 5b and 5b′, disposed to face the bottom surface of the mounting table 2, cooled by the chiller 5a; and an insulating supporting member SP, disposed between a bottom surface of the heat transfer mechanism 5b′ and the bottom portion of the processing chamber 1, for supporting the heat transfer mechanism 5b′. The supporting member SP may be made of an insulator such as alumina, quartz glass, or the like.

The ring-shaped heat transfer mechanisms 5b and 5b′ can become close to the bottom surface of the mounting table 2 over a large area, because they are disposed to face the bottom surface of the mounting table 2. Accordingly, the in-plane uniformity of the cooling for the mounting table 2 and the cooling efficiency can be improved. Since the heat transfer mechanisms 5b and 5b′ have the ring shape, they are partially supported by the supporting member SP.

Hereinafter, examples of the driving mechanism 6 and the rotation mechanism 7 will be described in detail.

As described above, the driving mechanism 6 performs linear movement.

The driving mechanism 6 is configured by combining a motor mechanism for controlling rotation including, e.g., a direct drive motor, and a vertical movement mechanism including, e.g., a motor, a ball screw, and a linear guide (linear slide mechanism). The vertical movement mechanism can drive the entire driving mechanism including the rotation mechanism by vertically moving a supporting table P supporting the rotation mechanism.

Specifically, the ball screw includes: a screw shaft 6a (male screw); a nut 6b (female screw), fitted on the screw shaft 6a, formed as one unit with the supporting table P while penetrating therethrough in a vertical direction; and steel balls disposed between the screw shaft 6a and the nut 6b. The screw shaft 6a is rotated by a motor M1, so that the nut 6b moves linearly along a lengthwise direction of the screw shaft 6a together with the supporting table P. The linear guide 6c supports the supporting table P such that the supporting table P can slide vertically, which restricts the movement of the supporting table P and the nut 6b in directions other than the vertical movement.

The motor M1 is a direct drive motor. When the screw shaft 6a that is coaxial with the motor M1 is rotated, the nut 6b is vertically moved and the supporting table P slides along a lengthwise direction of the linear guide 6c (vertical direction). The motor M1 and the linear guide 6c are fixed to an apparatus base (not shown), so that the supporting table P is moved with respect to the apparatus base.

The rotation mechanism 7 can be rotated by a direct drive motor connected to a rotation shaft 8b. The rotation shaft 5b is supported by a bearing BR. A magnetic fluid unit J serves as a wall for partitioning a vacuum state and an atmospheric pressure state.

Specifically, the rotation mechanism 7 of this embodiment includes a motor M2 fixed onto the supporting table P. The motor M2 is a direct drive motor and directly rotates the rotation shaft 8b. A magnetic fluid unit J (magnetic fluid seal) and the bearing BR are provided around the rotation shaft 8b. A space above the magnetic fluid unit J communicates with the inside of the processing chamber 1 maintained in a vacuum state (depressurized atmosphere). A space below the magnetic fluid unit J is maintained at an atmospheric pressure. The bearing BR and the magnetic fluid unit J are provided between the rotation shaft 8b and an inner surface of a supporting barrel 16. The magnetic fluid unit J blocks gas flow between an upper space and a lower space in the supporting barrel 16 fixed onto the supporting table P. An upper end of the supporting barrel 16 is fixed to an upper plate 17. The bellows 9 is fixed between the upper plate 17 and the processing chamber 1.

The structures of the driving mechanism 6 and the rotation mechanism 7 are not limited to the above-described ones and may be variously modified as long as the linear movement and the rotation can be achieved.

The processing apparatus further includes a control unit 100 for controlling the entire apparatus. The control unit 100 can control the power supply 15 for plasma generation (see FIG. 1) which supplies a power for plasma generation to the target, the rotation mechanism 7 for rotating the mounting table 2, and the driving mechanism 6.

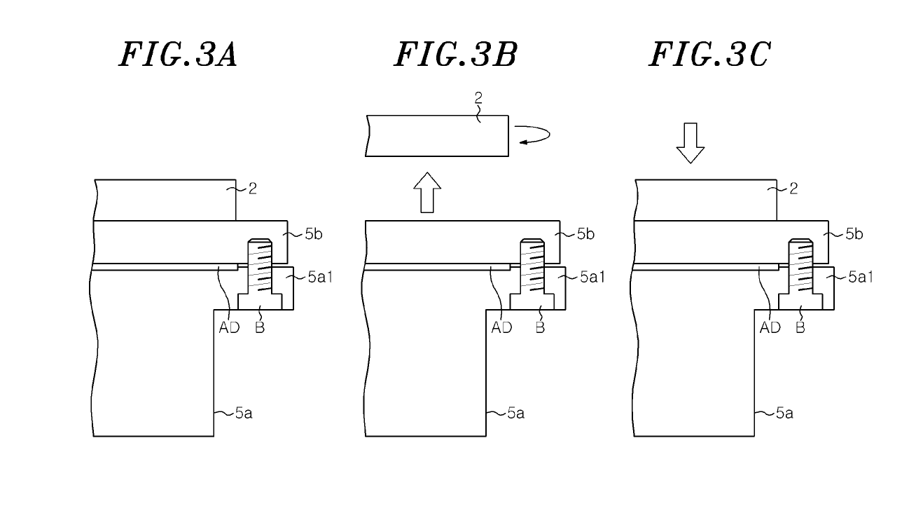

FIGS. 3A to 3C explain the movement of the mounting table.

The cooling head 5a1 of the chiller 5a and the heat transfer mechanism 5b are fixed by a bolt B. An adhesive AD is provided between the cooling head 5a1 and the heat transfer mechanism 5b to improve adhesivity therebetween. The adhesive AD is, e.g., an indium sheet.

When the heat transfer mechanism 5b and the mounting table 2 come close to each other (or come into caontact with each other) as shown in FIG. 3A, the mounting table 2 is cooled. Next, when the first rotation motor M1 of the driving mechanism 6 is controlled by the control unit, the mounting table 2 is moved upward as shown in FIG. 3B. When the second rotation motor M2 of the rotation mechanism 7 is controlled by the control unit, the mounting table 2 is rotated. In that state, the film formation is performed. After the film formation is completed, the control unit controls the second rotation motor M2 of the rotation mechanism 7 to stop the rotation. Then, the control unit controls the first rotation motor M1 of the driving mechanism 6 to move the mounting table 2 downward. Accordingly, the heat transfer mechanism 5b and the mounting table 2 become close to each other or in contact with each other as shown in FIG. 3C, and the cooling is performed. Between steps shown in FIGS. 3B and 3C, a substrate as a processing target may be exchanged.

As described above, in the above processing apparatus, the distance between the mounting table 2 and the cooling mechanism can be changed by vertically moving the mounting table 2.

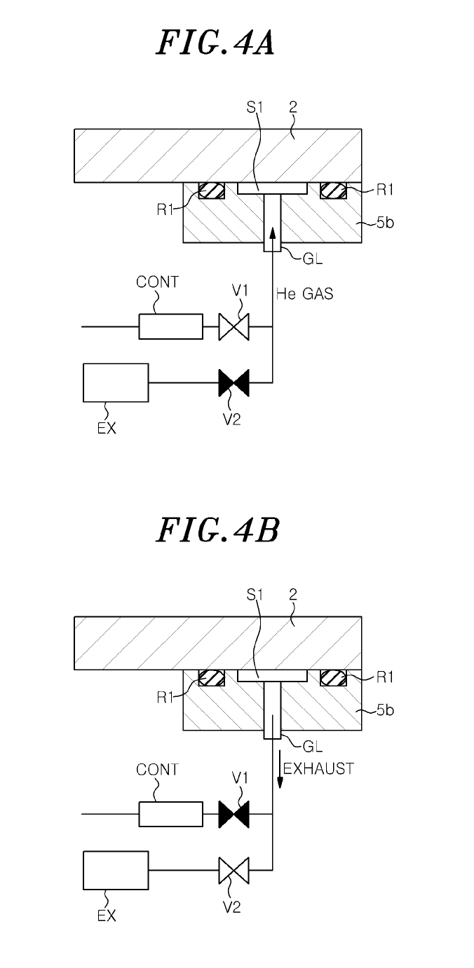

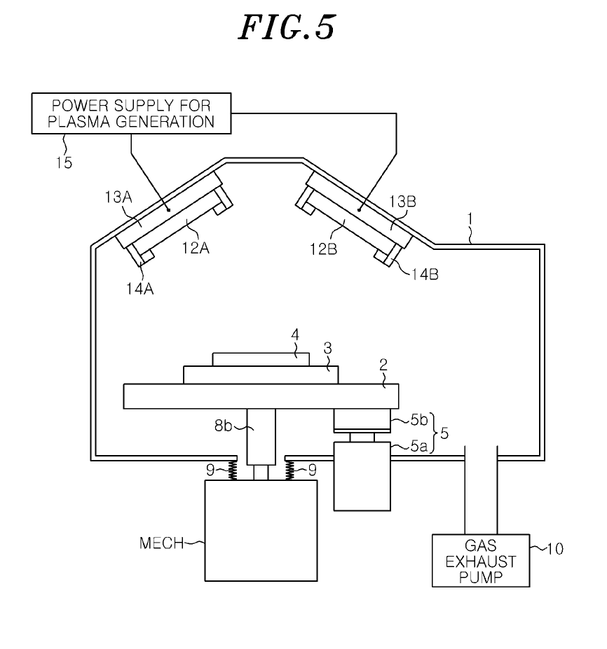

FIGS. 4A and 4B explain the cooling of the mounting table.

In the above-described cooling mechanism 5, a cooling gas passage GL through which a heat transfer gas (He gas or the like) is supplied is provided in a space S1 between the mounting table 2 and the cooling mechanism 5 (the heat transfer mechanism 5b). Although the cooling gas passage GL is provided in the heat transfer mechanism 5b, the cooling gas passage GL may extend to the outside of the heat transfer mechanism 5b. When the heat transfer gas is supplied through the cooling gas passage GL, the heat of the mounting table 2 is effectively transferred to the cooling mechanism 5 (the heat transfer mechanism 5b) by the gas.

FIG. 4A shows a state in which the He gas is supplied into the space S1 through the cooling gas passage GL. In that case, the first valve V1 is opened and the second valve V2 is closed. The He gas is supplied at a constant level controlled by an automatic pressure control unit CONT. The He gas is supplied during the cooling process, while the supply of the He gas is stopped during the film formation.

FIG. 4B shows an exhaust operation in which the first valve V1 is closed and the second valve V2 is opened. The second valve V2 is connected to a gas exhaust system EX, so that a gas in the space S1 is exhausted. After the mounting table 2 is sufficiently cooled as shown in FIG. 4A and a residual He gas is exhausted as shown in FIG. 4B, the mounting table 2 is moved upward and the film formation is performed.

The above cooling mechanism preferably includes a chiller that can be cooled to about 50K and has a cooling capacity of about 100 W or above. As for the aforementioned adhesive AD (buffering material), it is possible to use polytetrafluoroethylene, graphite, induim, or the like (see FIGS. 3A to 3C).

FIG. 5 shows a processing apparatus in which a plurality of targets is provided.

This processing apparatus have the same configuration as that of the processing apparatus shown in FIG. 1 except that a plurality of targets is provided. A predetermined power is supplied from the power supply 15 for plasma generation to the target 12 through the target holder 13. In FIG. 5, two kinds of targets are exemplified, which are distinguished as A and B as suffix of each reference numerals.

A first target 12A and a second target 12B are positioned above the substrate 4. When seen from the top, they are partially overlapped with the substrate 4. A normal line of each of the first target 12A and the second target 12B is directed to the center of the substrate 4. Atoms or molecules sputtered from the targets are properly irradiated to the substrate 4. Since the substrate 4 rotates, the normals line of the first target 12A and the second target 12B are not necessarily directed to the center of the substrate 4.

In the actual sputtering, the power for plasma generation may be supplied to one of the first target 12A and the second target 12B or to both of them.

The magnetic film can be used in a wide range such as a Hard disk drive HDD, a MRAM, a STT-RAM or the like. A technique for performing sputtering in a state where the substrate is cooled to an extremely low temperature is very advantageous in manufacturing a magnetic film. For example, it is possible to amorphize a magnetic film of a TMR film used for a reading head unit of a HDD and also possible to control a thermal stress or an internal stress of the magnetic film, a crystal grain diameter, or the like.

The TMR film has a multilayer structure in which a plurality of magnetic films or nonmagnetic films is laminated and is used in a wide range such as a HDD, a STT-RAM, or the like. Therefore, the processing apparatus for performing sputtering preferably has a structure in which a plurality of sputtering targets can be used in a single module. In the case of using a plurality of sputtering targets, an inclined incidence offset rotary deposition-type is employed to obtain sufficient in-plane uniformity of the substrate (see FIG. 5).

FIG. 6 is a timing chart showing relation between a processing time and a substrate temperature. This timing chart shows the case of using a plurality of targets.

Time t0 to Time t1: A period T1 is a cooling period of the mounting table 2. The cooling of the mounting table 2 is started at a room temperature RT and continued until the temperature becomes sufficiently lower than, e.g., 100K by the cooling mechanism 5. Accordingly, the temperature of the substrate 4 is cooled to the same level as that of the mounting table 2.

Time t1 to Time t2: A period T2 is a preparation period before the film formation starts. The mounting table 2 is raised to be separated from the cooling mechanism 5 and rotated steadily. At this time, the temperature of the mounting table is slightly increased due to heat dissipation by radiation.

Time t2 to Time t3: A period T3 is a period in which the film formation (sputtering) is carried out. Here, the case in which only one of the two targets (see FIG. 5) is sputtered will be described as an example. The temperature of the substrate 4 (mounting table 2) is increased due to heat input and radiation by the plasma.

Time t3 to Time t4: A period T4 is a cooling period of the mounting table for sputtering the other one of the two targets. The rotation of the mounting table 2 is stopped and, then, the mounting table 2 is lowered to approach the cooling mechanism 5. The cooling mechanism 5 further cools the mounting table 2 having a temperature of 100K or less until the temperature becomes sufficiently lower than 100K. Accordingly, the temperature of the substrate 4 is decreased to substantially the same level as that of the mounting table 2.

Time t4 to Time t5: A period T5 is a preparation period before the film formation starts. The mounting table 2 is raised to be separated from the cooling mechanism 5 and rotated steadily. At this time, the temperature of the substrate 4 (mounting table 2) is slightly increased due to heat dissipation by radiation.

Time t5 to Time t6: A period T6 is a period in which the film formation (sputtering) is performed. Here, the case in which only the other one of the two targets (see FIG. 5) is sputtered will be described as an example. The temperature of the substrate 4 (the mounting table 2) is increased due to heat input and radiation by the plasma.

The above control is performed by the control unit 100 (see FIG. 2). In other words, the control unit 100 sequentially executes a step of setting the second state (close state) by the driving mechanism 6 and cooling the mounting table 2, a step of setting the first state (separating state) by the driving mechanism 6 and rotating the mounting table 2 by the rotation mechanism 7, and a step of sputtering the target 12 by plasma generated by supplying a power from the power supply 15 for plasma generation to the target 12.

The control unit can control the driving mechanism 6, the rotation mechanism 7, and the power supply 15 for plasma generation by transmitting control signals to the respective device. In this processing apparatus, the sputtering can be performed in a state where both of sufficient cooling and rotation are achieved.

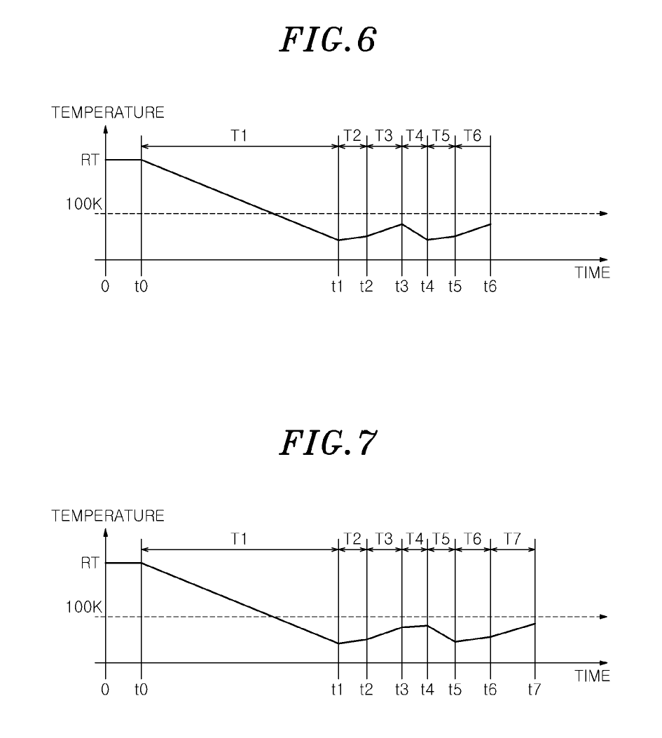

FIG. 7 is another timing chart showing relation between the processing time and the substrate temperature. This timing chart shows the case of processing a plurality of substrates.

Time t0 to Time t1: A period T1 is a cooling period of the mounting table 2. The cooling of the mounting table 2 at a room temperature RT is started by the cooling mechanism 5 and continued until the temperature becomes sufficiently lower than, e.g., 100K. Accordingly, the temperature of the substrate 4 is decreased to substantially the same level as that of the mounting table 2.

Time t1 to Time t2: A period T2 is a preparation period before the film formation is carried out. The mounting table 2 is raised to be separated from the cooling mechanism 5 and rotated steadily. At this time, the temperature of the mounting table is slightly increased due to heat dissipation by radiation.

Time t2 to Time t3: A period T3 is a period in which the film formation (sputtering) is carried out. Here, the target is sputtered. The temperature of the substrate 4 (mounting table 2) is increased due to heat input and radiation by the plasma.

Time t3 to Time t4: A period T4 is a period for stopping the rotation of the mounting table 2, unloading a first substrate that has been processed to an external transfer chamber by the transfer mechanism, and loading another substrate (second substrate) into the processing chamber from the transfer chamber.

Time t4 to Time t5: A period T5 is a cooling period of the mounting table on which a new substrate is mounted. The mounting table is lowered to approach the cooling mechanism 5. The cooling mechanism 5 further cools the mounting table 2 having a temperature of 100K or less until the temperature becomes sufficiently lower than 100K. Accordingly, the temperature of the new substrate 4 is decreased to substantially the same level as that of the mounting table 2.

Time t5 to Time t6: A period T6 is a preparation period before the plasma processing starts. The mounting table 2 is raised to be separated from the cooling mechanism 5 and rotated steadily. At this time, the temperature of the mounting table is slightly increased due to heat dissipation by radiation.

Time t6 to Time t7: A period T7 is a period in which the film formation (sputtering) is performed on the new substrate. Here, the temperature of the substrate 4 (the mounting table 2) is increased due to heat input and radiation by the plasma.

The above-described control is performed by the control unit 100 (see FIG. 2). In other words, the processing apparatus further includes a transfer mechanism (not shown) for loading the substrate 4 onto the mounting table 2 in the processing chamber 1 from the outside of the processing chamber 1 and unloading the substrate 4 on the mounting table 2 in the processing chamber 1 to the outside of the processing chamber 1. The control unit 100 sequentially executes the step of unloading the first substrate mounted on the mounting table 2 to the outside of the processing chamber by controlling the transfer mechanism and the step of loading the second substrate from the outside of the processing chamber 1 and mounting the second substrate onto the mounting table. The object to be processed can be loaded/unloaded by control signals transmited to the transfer mechanism from the control unit 100. Alternatively, the loading/unloading of the object to be processed may be performed by control signals transmited from an additional control unit (not shown) other than the control unit 100.

The mounting table 2 can be vertically moved within a range where a distance from a surface of the mounting table 2 to a center of a surface of the target which faces to the mounting table 2 is greater than or equal to about 150 mm and smaller than or equal to about 400 mm. The mounting table 2 can rotate at a speed greater than or equal to 0 rpm and lower than or equal to 100 rpm in order to maintain the uniformity of the film.

The electrostatic chuck 3 is provided on the above mounting table 2. The electrostatic chuck 3 may have a unipolar or a bipolar structure for electrostatic attraction. He gas may flow on a backside of the electrostatically attracted substrate for increasing the cooling efficiency. It is also possible to form a groove on the surface of the electrostatic chuck 3 so that He gas can flow between the substrate and the surface of the electrostatic chuck. Further, a mechanism for mechanically fixing the substrate to the mounting table may be employed instead of the electrostatic chuck.

While the disclosure has been shown and described with respect to the embodiments, it will be understood by those skilled in the art that various changes and modifications may be made without departing from the scope of the disclosure as defined in the following claims.

What is claimed is:

1. A processing apparatus comprising:
a processing chamber where a sputtering target is provided;
a rotatable mounting table, provided in the processing chamber and configured to mount thereon an object to be processed;
a cooling mechanism configured to cool the mounting table; and
a driving mechanism configured to change a relative position of the mounting table with respect to the cooling mechanism,
wherein the driving mechanism changes a conductivity of heat from the mounting table to the cooling mechanism at least by switching a first state in which the mounting table and the cooling mechanism are separated from each other and a second state in which the mounting table and the cooling mechanism become close to each other.

2. The processing apparatus of claim 1, wherein the driving mechanism vertically moves the mounting table.

3. The processing apparatus of claim 1, wherein the cooling mechanism includes a cooling gas passage through which a heat transfer gas is supplied to a space between the mounting table and the cooling mechanism.

4. The processing apparatus of claim 2, wherein the cooling mechanism includes a cooling gas passage through which a heat transfer gas is supplied to a space between the mounting table and the cooling mechanism.

5. The processing apparatus of claim 1, wherein the cooling mechanism includes:
a ring-shaped heat transfer mechanism, disposed to face a bottom surface of the mounting table and cooled by a chiller; and
an insulating supporting member, disposed between a bottom surface of the heat transfer mechanism and a bottom portion of the processing chamber to support the heat transfer mechanism.

6. The processing apparatus of claim 2, wherein the cooling mechanism includes:
a ring-shaped heat transfer mechanism, disposed to face a bottom surface of the mounting table and cooled by a chiller; and
an insulating supporting member, disposed between a bottom surface of the heat transfer mechanism and a bottom portion of the processing chamber to support the heat transfer mechanism.

7. The processing apparatus of claim 3, wherein the cooling mechanism includes:
a ring-shaped heat transfer mechanism, disposed to face a bottom surface of the mounting table and cooled by a chiller; and
an insulating supporting member, disposed between a bottom surface of the heat transfer mechanism and a bottom portion of the processing chamber to support the heat transfer mechanism.

8. The processing apparatus of claim 4, wherein the cooling mechanism includes:
a ring-shaped heat transfer mechanism, disposed to face a bottom surface of the mounting table and cooled by a chiller; and
an insulating supporting member, disposed between a bottom surface of the heat transfer mechanism and a bottom portion of the processing chamber to support the heat transfer mechanism.

9. The processing apparatus of claim 1, further comprising:
a power supply for plasma generation configured to supply a power for plasma generation to the sputtering target;
a rotation mechanism configured to rotate the mounting table; and
a control unit configured to control the power supply for plasma generation, the rotation mechanism, and the driving mechanism,
wherein the control unit executes:
setting the second state by the driving mechanism and cooling the mounting table;
setting the first state by the driving mechanism and rotating the mounting table by the rotation mechanism; and
sputtering the sputtering target by plasma generated by supplying a power from the power supply for plasma generation to the sputtering target.

10. The processing apparatus of claim 2, further comprising:
a power supply for plasma generation configured to supply a power for plasma generation to the sputtering target;
a rotation mechanism configured to rotate the mounting table; and
a control unit configured to control the power supply for plasma generation, the rotation mechanism, and the driving mechanism,
wherein the control unit executes:
setting the second state by the driving mechanism and cooling the mounting table;
setting the first state by the driving mechanism and rotating the mounting table by the rotation mechanism; and
sputtering the sputtering target by plasma generated by supplying a power from the power supply for plasma generation to the sputtering target.

11. The processing apparatus of claim 3, further comprising:
a power supply for plasma generation configured to supply a power for plasma generation to the sputtering target;
a rotation mechanism configured to rotate the mounting table; and
a control unit configured to control the power supply for plasma generation, the rotation mechanism, and the driving mechanism,
wherein the control unit executes:
setting the second state by the driving mechanism and cooling the mounting table;
setting the first state by the driving mechanism and rotating the mounting table by the rotation mechanism; and
sputtering the sputtering target by plasma generated by supplying a power from the power supply for plasma generation to the sputtering target.

12. The processing apparatus of claim 4, further comprising:
a power supply for plasma generation configured to supply a power for plasma generation to the sputtering target;
a rotation mechanism configured to rotate the mounting table; and
a control unit configured to control the power supply for plasma generation, the rotation mechanism, and the driving mechanism,
wherein the control unit executes:
setting the second state by the driving mechanism and cooling the mounting table;
setting the first state by the driving mechanism and rotating the mounting table by the rotation mechanism; and
sputtering the sputtering target by plasma generated by supplying a power from the power supply for plasma generation to the sputtering target.

13. The processing apparatus of claim 1, further comprising:
a transfer mechanism configured to load the object onto the mounting table in the processing chamber from the outside of the processing chamber and unload the object on the mounting table in the processing chamber to the outside of the processing chamber; and
a control unit configured to control the transfer mechanism,
wherein the control unit controls the transfer mechanism to sequentially executes:
unloading a first object on the mounting table to the outside of the processing chamber; and
loading a second object from the outside of the processing chamber and mounting the second object on the mounting table.

14. The processing apparatus of claim 2, further comprising:
a transfer mechanism configured to load the object onto the mounting table in the processing chamber from the outside of the processing chamber and unload the object on the mounting table in the processing chamber to the outside of the processing chamber; and
a control unit configured to control the transfer mechanism,
wherein the control unit controls the transfer mechanism to sequentially executes:
unloading a first object on the mounting table to the outside of the processing chamber; and
loading a second object from the outside of the processing chamber and mounting the second object on the mounting table.

15. The processing apparatus of claim 3, further comprising:
a transfer mechanism configured to load the object onto the mounting table in the processing chamber from the outside of the processing chamber and unload the object on the mounting table in the processing chamber to the outside of the processing chamber; and
a control unit configured to control the transfer mechanism,
wherein the control unit controls the transfer mechanism to sequentially executes:
unloading a first object on the mounting table to the outside of the processing chamber; and
loading a second object from the outside of the processing chamber and mounting the second object on the mounting table.

16. The processing apparatus of claim 4, further comprising:
a transfer mechanism configured to load the object onto the mounting table in the processing chamber from the outside of the processing chamber and unload the object on the mounting table in the processing chamber to the outside of the processing chamber; and
a control unit configured to control the transfer mechanism,
wherein the control unit controls the transfer mechanism to sequentially executes:
unloading a first object on the mounting table to the outside of the processing chamber; and
loading a second object from the outside of the processing chamber and mounting the second object on the mounting table.

17. The processing apparatus of claim 9, further comprising:
a transfer mechanism configured to load the object onto the mounting table in the processing chamber from the outside of the processing chamber and unload the object on the mounting table in the processing chamber to the outside of the processing chamber,
wherein the control unit controls the transfer mechanism to sequentially executes:
unloading a first object on the mounting table to the outside of the processing chamber; and
loading a second object from the outside of the processing chamber and mounting the second object on the mounting table.

18. The processing apparatus of claim 10, further comprising:
a transfer mechanism configured to load the object onto the mounting table in the processing chamber from the outside of the processing chamber and unload the object on the mounting table in the processing chamber to the outside of the processing chamber,
wherein the control unit controls the transfer mechanism to sequentially executes:
unloading a first object on the mounting table to the outside of the processing chamber; and
loading a second object from the outside of the processing chamber and mounting the second object on the mounting table.

19. The processing apparatus of claim 11, further comprising:
a transfer mechanism configured to load the object onto the mounting table in the processing chamber from the outside of the processing chamber and unload the object on the mounting table in the processing chamber to the outside of the processing chamber,
wherein the control unit controls the transfer mechanism to sequentially executes:
unloading a first object on the mounting table to the outside of the processing chamber; and
loading a second object from the outside of the processing chamber and mounting the second object on the mounting table.

20. The processing apparatus of claim 12, further comprising:
a transfer mechanism configured to load the object onto the mounting table in the processing chamber from the outside of the processing chamber and unload the object on the mounting table in the processing chamber to the outside of the processing chamber,
wherein the control unit controls the transfer mechanism to sequentially executes:
unloading a first object on the mounting table to the outside of the processing chamber; and
loading a second object from the outside of the processing chamber and mounting the second object on the mounting table.
